(19) United States
(12) Patent Application Publication
(10) Pub. No.: US 2007/0161822 A1
(43) Pub. Date: Jul. 12, 2007

(54) Oligofluorene-based compounds and the use thereof

(76) Inventors: Feng-Wen Yen, Hsinchu City (TW); Chao-Yu Chiu, Hsinchu City (TW); Cheng-Hao Chang, Miaoli County (TW); I-Feng Lin, Taoyuan County (TW); Pei-Chi Yen, Hsinchu City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/328,187

(22) Filed: Jan. 10, 2006

(51) Int. Cl. H01L 51/54; C09K 11/06

(52) U.S. Cl. 564/426; 428/690; 428/917; 313/504; 313/506; 585/26; 585/27; 564/433; 564/434; 257/40; 257/E51.032; 257/E51.049; 257/E51.051

(57) ABSTRACT

The present invention discloses an oligofluorene-based compound, wherein the general formula of the oligofluorene-based compound is as following: 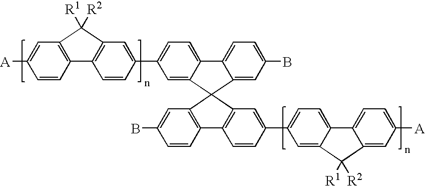 , wherein n is an integer of 0 to 3, A is polyaryl moiety or amino group, and B is amino group or hydrogen. Furthermore, the mentioned oligofluorene-based compound can be used as electro-luminescent materials or host-guest materials.

### BACKGROUND OF THE INVENTION

1. Field of the Invention

The present invention is generally related to oligofluorene-based compounds, and more particularly to oligofluorene-based compounds and their use as electro-luminescent materials.

2. Description of the Prior Art

In recent years, there has been considerable interest in developing blue organic light-emitting devices (OLEDs) with high efficiency, deep-blue color, and long operational lifetime. The deep-blue color is defined arbitrarily as having blue electroluminescent (EL) emission with a Commission Internationale de l'Eclairage y coordinate value (CIE_{y}) of <0.15. Such emitters can effectively reduce the power consumption of a full-color OLED and can also be utilized to generate light of other colors by energy cascade to a suitable emissive dopant.

It is well known that a guest-host doped emitter system can significantly improve device performance in terms of EL efficiency and emissive color, as well as operational lifetime. Although many blue host materials have been reported, such as anthracene, di(styryl)arylene, terfluorenes, and tetra(phenyl)silyl derivatives, blue-doped emitter systems having all the attributes of high EL efficiency, long operational lifetime, and deep-blue color, are rare. Some conventional materials exhibit sky blue color or blue color, but these materials are not yet saturated enough for commercial full-color applications. Moreover, other conventional materials possess some disadvantages for use in long-lifetime OLED devices such as their relatively low glass transition temperature, ease of crystallization, color instability and reduced efficiency, has been a crucial problem that has limited the application of full-color OLED. Therefore, new blue emitting materials are still needed corresponding to increasing thermal stability, achieving deep-blue emission, so as to improve the efficiency and to extend the lifetime of OLEDs.

### SUMMARY OF THE INVENTION

In accordance with the present invention, new oligofluorene-based compounds and their use are provided. These new oligofluorene-based compounds can overcome the drawbacks of the mentioned conventional materials.

One object of the present invention is to employ spirobifluorene as core structure, which is with high photoluminescence (PL) and electroluminescence (EL) efficiencies, good thermal stability, and ready color-tuning through the introduction of fluorine-based moiety on 2,2′ positions.

Another object of the present invention is to provide a multilayered OLED with low driving voltage, high efficiency, and high thermal stability, wherein the OLED comprises the mentioned oligofluorene-based compounds as electro-luminescent materials or host-guest materials. The glass transition temperature (T_{g}) and thermal degradation temperature (T_{d}) of the mentioned oligofluorene-based are higher than 150° C. and 400° C. respectively. Therefore, this present invention does have the economic advantages for industrial applications.

Accordingly, the present invention discloses an oligofluorene-based compound, wherein the general formula of the oligofluorene-based compound is as following: 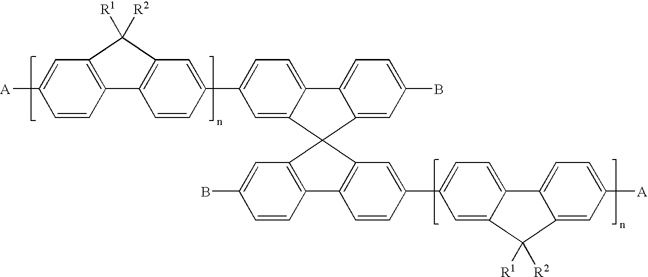
wherein n is an integer of 0 to 3,
when n=0, A is a polyaryl moiety, B is 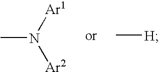
when 1≦n≦3, A is a polyaryl moiety or 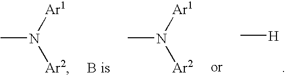
Furthermore, the mentioned oligofluorene-based compound can be used as electro-luminescent materials or host-guest materials.

### BRIEF DESCRIPTION OF THE DRAWINGS

FIG. 1A shows glass transition temperature (Tg) of compound 1;

FIG. 1B shows thermal degradation temperature (Td) of compound 1;

FIG. 1C shows PL spectra for compound 1;

FIG. 2A shows glass transition temperature (Tg) of compound 8;

FIG. 2B shows thermal degradation temperature (Td) of compound 8;

FIG. 2C shows PL spectra for compound 8;

FIG. 3A shows PL spectra for device 1;

FIG. 3B shows plots of luminance v. voltage for devices 1;

FIG. 3C shows plots of EL efficiency v. current density for devices 1;

FIG. 4A shows PL spectra for device 2-1 to device 2-5;

FIG. 4B shows plots of luminance v. voltage for device 2-1 to device 2-5; and

FIG. 4C shows plots of EL efficiency v. current density for device 2-1 to device 2-5.

### DESCRIPTION OF THE PREFERRED EMBODIMENTS

What probed into the invention are oligofluorene-based compounds and the use thereof. Detailed descriptions of the production, structure and elements will be provided in the following in order to make the invention thoroughly understood. Obviously, the application of the invention is not confined to specific details familiar to those who are skilled in the art. On the other hand, the common elements and procedures that are known to everyone are not described in details to avoid unnecessary limits of the invention. Some preferred embodiments of the present invention will now be described in greater detail in the following. However, it should be recognized that the present invention can be practiced in a wide range of other embodiments besides those explicitly described, that is, this invention can also be applied extensively to other embodiments, and the scope of the present invention is expressly not limited except as specified in the accompanying claims.

Definition

The term “thermal degradation temperature (T_{d})” herein refers to the temperature when the weight loss of a heated specimen being 0.5 wt %.

In a first embodiment of the present invention, an oligofluorene-based compound is disclosed, wherein the general formula of the oligofluorene-based compound is as following: 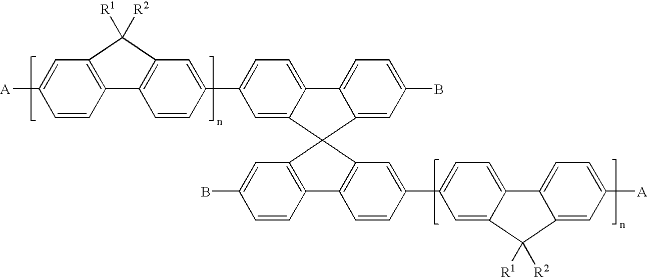
, wherein n is an integer of 0 to 3;
when n=0, A is a polyaryl moiety, and B is 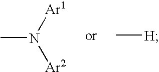
when 1≦n≦3, A is a polyaryl moiety or 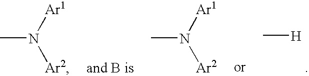
Furthermore, Ar¹ and Ar² can be identical or different, and Ar¹ and Ar² are independently selected from the group consisting of: aryl moiety, hetero cycle, multiple fused ring, multiple fused ring with hetero atom(s).

In this embodiment, the polyaryl moiety is selected from the group consisting of:

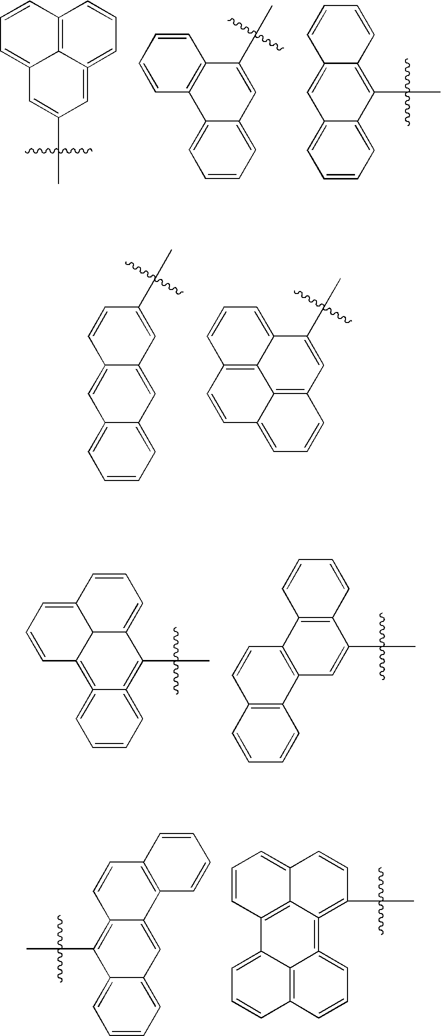

Moreover, the mentioned oligofluorene-based compound can be used as host material or as guest dopant material in organic electroluminescence devices. When the compound is used as host material in organic electroluminescence devices, A is a polyaryl moiety, and B is hydrogen atom. When the compound is used as guest dopant material in organic electroluminescence devices, there are three preferred cases: (1) n=0, A is a polyaryl moiety, B is 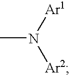
(2) when 1≦n≦3, A is a polyaryl moiety, B is 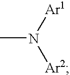
and (3) when 1≦n≦3, A is

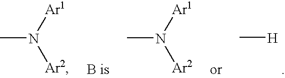

In this embodiment, some oligofluorene-based compounds are listed in Table 1.

TABLE 1

| | Structure formula |
|---|---|
| Com- pound 1 | 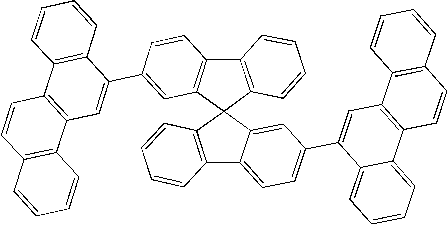 |
| Com- pound 2 | 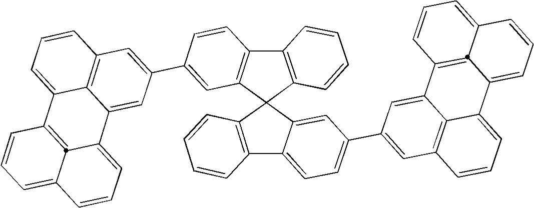 |
| Com- pound 3 | 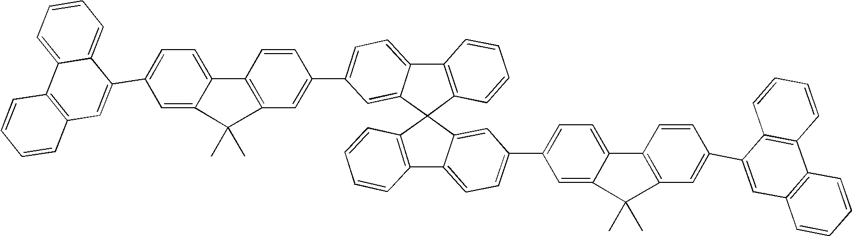 |
| Com- pound 4 | 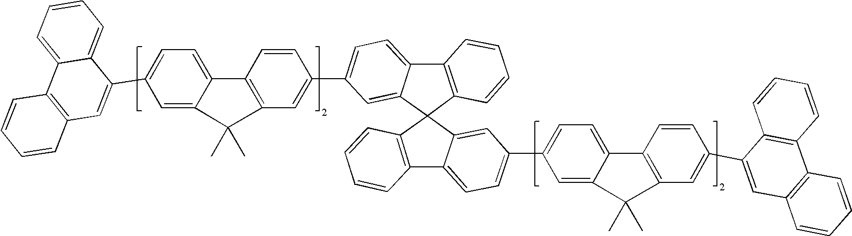 |
| Com- pound 5 | 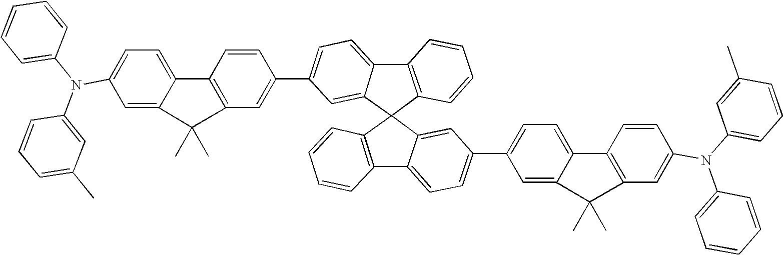 |
| Com- pound 6 | 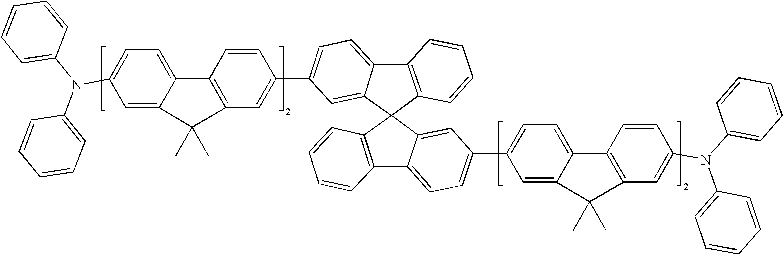 |
| Com- pound 7 | 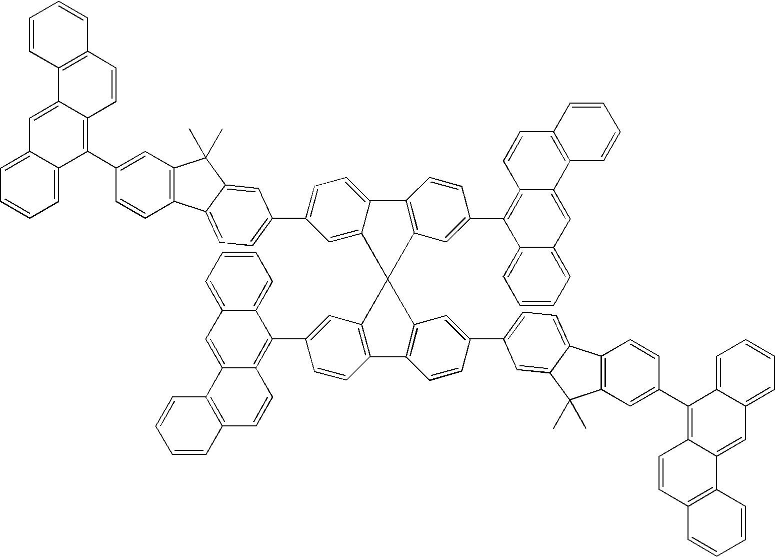 |
| Com- pound 8 | 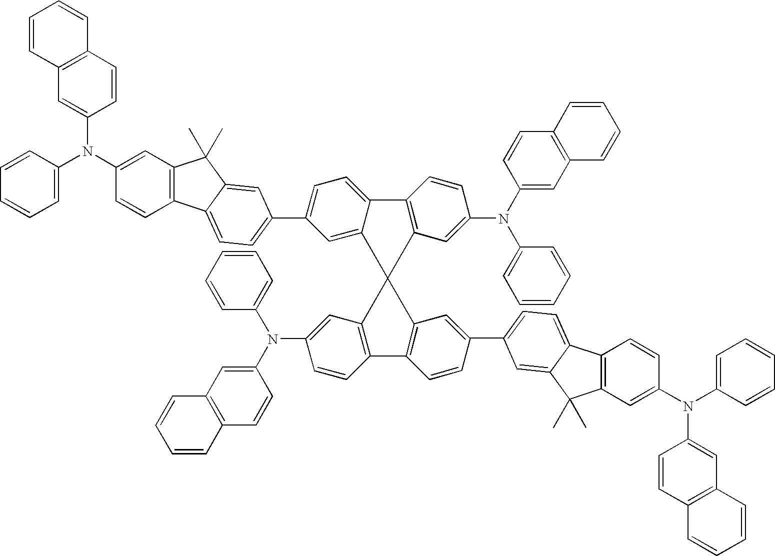 |

Forming methods of the mentioned oligofluorene-based compounds, such as compound 1 to compound 8, have been carried out by the Suzuki coupling reaction as a key step, and using di-substituted spirobiflurene, such as 2,2′-dihalo-9,9′-spirobiflurene, 2,2′-diboronic acid-9,9′-spirobiflurene, or 2,2′-diboronic ester-9,9′-spirobiflurene as the starting material. In general speaking, promising carbon-carbon couplings are the ones combining an organic boronic acid/ester with an organic electrophile in the presence of a palladium catalyst and base, also known as Suzuki couplings. Synthesis chemists all over the world are becoming convinced that Suzuki couplings will take an important place in the C—C bond forming tool kit. Suzuki chemistry provides an efficiently, cost effectively, mildly and environmentally safe methodology for the chemo-selective formation of C—C bonds on an industrial scale. As opposed to the Stille coupling, Suzuki reagents do not involve highly toxic (tin) reagents.

### EXAMPLE 1

### Synthesis of 2,2′-dibromo-9,9′-spirobiflurene

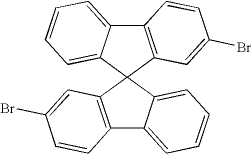

To a 100 mL, three-necked, flask was added a solution of spirobifluorene (10 g) in CH₂Cl₂ (100 mL). The solution was heated to reflux, and a solution of bromide (5 g) dissolved in 20 ml CH₂Cl₂ was added into the refluxing solution drop by drop. The mixture was then stirred overnight. After completion of the reaction, the reaction mixture was washed by 80 ml water for 2 times and saturated K₂CO₃ (aq.) for 1 time. The organic layer was separated, dehydrated by MgSO₄, and vacuum concentrated to form crude product. Finally, crude product was purified by column chromatography to obtain wanted product 3.7 g (24%).

### EXAMPLE 2

### Synthesis of 2,2′-diboronic ester-9,9′-spirobiflurene

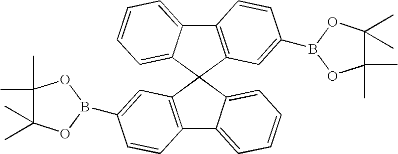

To a 100 mL, two-necked, dehydrated flask was added 2,2′-dibromo-9,9′-spirobiflurene (1.0 g; 2.1 mmol) in THF (15 mL). The solution was first cooled to −78° C., and n-BuLi (4.0 ml; 3.0 eq.) was then added into the cooled solution drop by drop. After completion of the n-BuLi adding, the mixture was stand for 1 hour at −78° C., and 2-isopropoxy-4,4,5,5-tetramethyl-[1,3,2]-dioxaborolane (1.3 ml; 3.0 eq.) was subsequently added into the mixture, and then stirred for another 30 minutes. Next, the mixture was heated to room temperature (about 20° C.) and stirred overnight (reaction as shown in scheme 2). After completion, reaction was quenched by water, and vacuum concentrated. After extracted with CH₂Cl₂, concentrated, and re-crystallized with n-pentane, white powders are obtained (923 mg, 75%).

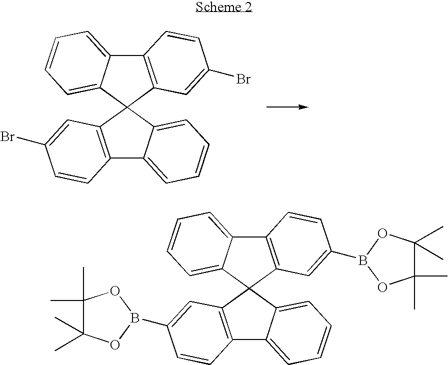

### EXAMPLE 3

### Synthesis of Compound 1

Referring to scheme 3-1, At room temperature and under nitrogen atmosphere, a solution of Mg (0.5 g; 21 mmole) and Iodine (0.2 g; 0.8 mmole) in THF (10 mL) was added into a 100 mL three-necked flask. The solution was heated to 60° C., and a solution of bromochrysene (5.4 g; 17.6 mmole) dissolved in 10 mL THF was added into the heated solution drop by drop. The mixture was then stirred for 2 hours. After completion of the reaction, the reaction mixture was cooled to room temperature, and subsequently iced at −15° C. for 10 minutes. Next, a solution of trimethyl borate (1.8 g; 17.3 mmole) dissolved in 10 mL THF was added into the iced mixture drop by drop. After completion of the trimethyl borate adding, the iced mixture was stand for 30 minutes at −15° C., and then heated to room temperature, stirred for another 24 hours. After completion, solvent THF was removed by vacuum concentration, and 50 mL CH₂Cl₂ and 100 mL water were subsequently added. The organic layer was separated, dehydrated, filtered, and the filtrate was dropped into 100 mL methanol to obtain solids. Finally, the solids were filtered and dried to get chrysene-boronic acid 3.64 g (yield 76%).

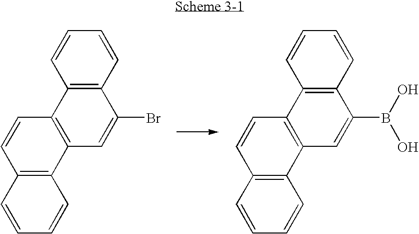

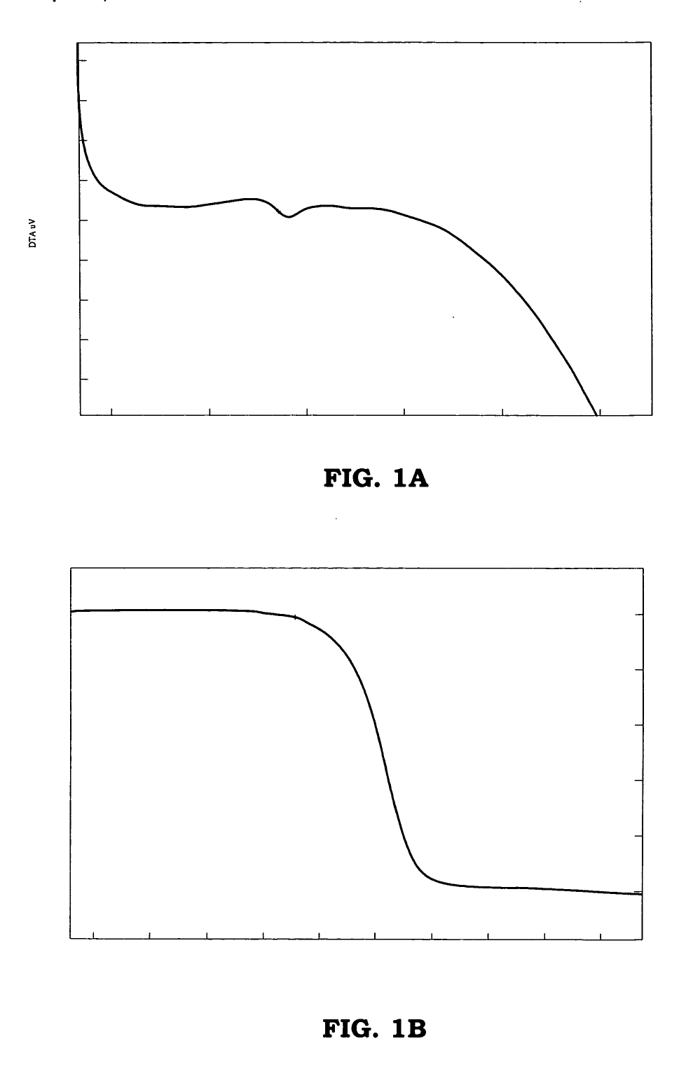

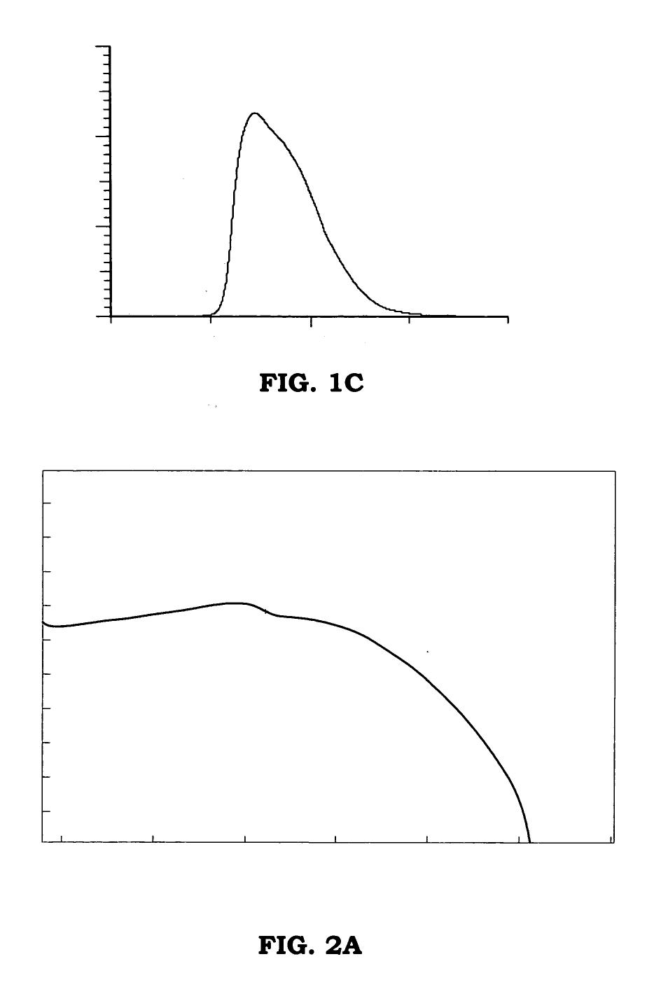

To a 500 mL, three-necked flask was added 2,2′-dibromo-9,9′-spirobiflurene (15 g; 31.6 mmol), chrysene-boronic acid (23.4 g), 2 M Na₂CO₃ (48 mL), tetrakis(triphenylphosphine)palladium(0) [0.73 g; 0.63 mmole], 2-(Dicyclo-hexylphosphino)biphenyl (0.55 g; 1.6 mmole) in toluene (225 mL). The solution is heated to 130° C. and stirred for 24 hours. After completion of the reaction, the reaction mixture is thermo filtrated; the filtrate was cooled to room temperature, and dropped into 1000 mL methanol to obtain solids. Finally, the solids were filtered and dried to get compound 1 12.2 g (yield 51%). MS (m/z, FAB⁺), 768. T_{g}=185.2° C. (as shown in FIG. 1A), T_{d}=478° C. (as shown in FIG. 1B), and FIG. 1C shows the PL spectrum of compound 1 with λₘₐₓ=445.4 nm.

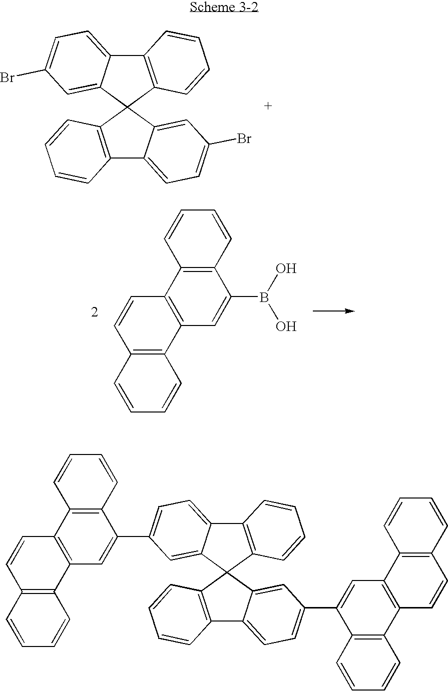

### EXAMPLE 4

### Synthesis of Dibromo Intermediate for Synthesis of Compound 3 and Compound 5

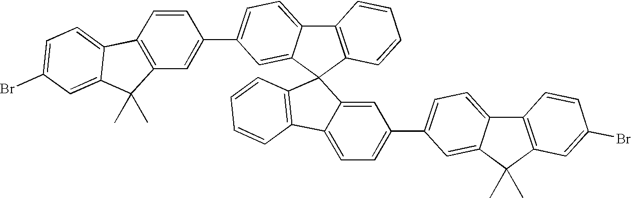

To a 100 mL, two-necked flask was added 2,2′-diboronic ester-9,9′-spirobiflurene (923 mg), Pd(PPh₃)₄ (91.42 mg; 5 mol %) and 2,7-dibromo-9,9′-dimethylfluorene (688.5 mg). Next, the flask was vacuumed, and then 80 mL deoxygened toluene, 1 mL K₂CO_{3(aq)}, and 2 mL P(t-Bu)_{3(aq)} were added respectively. The mixture was heated to reflux for 2 days (reaction as shown in scheme 4). After completion of the reaction, crude product was extracted with CH₂Cl₂, dehydrated with by MgSO₄ and concentrated. Finally, crude product was purified by column chromatography on silica gel (CH₂Cl₂/Hexane=⅓), so as to obtain white solids (25 mg, yield 18%).

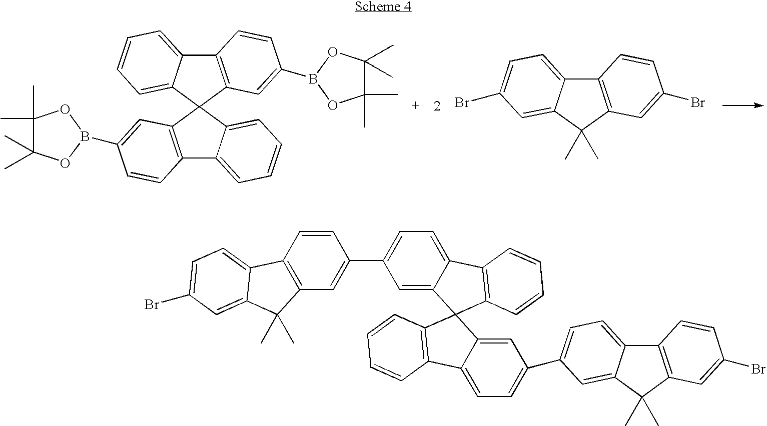

### EXAMPLE 5

### Synthesis of Dibromo Intermediate for Synthesis of Compound 4 and Compound 6

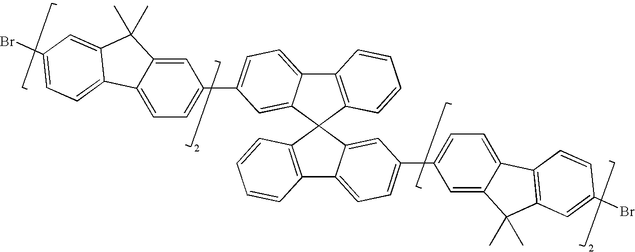

To a 250 mL, two-necked, flask was added 2,2′-diboronic ester-9,9′-spirobiflurene (2 g), Pd(PPh₃)₄ (0.2 g; 5 mol %) and dibromo-bis-(9,9′-dimethylfluorene) (1.91 g). Next, the flask was vacuumed, and then 200 ml deoxygened toluene, 2 mL K₂CO_{3(aq)}, and 5 mL P(t-Bu)_{3(aq)} were added respectively. The mixture was heated to reflux for 2 days (reaction as shown in scheme 5). After completion of the reaction, crude product was extracted with CH₂Cl₂, dehydrated with by MgSO₄ and concentrated. Finally, crude product was purified by column chromatography on silica gel (CH₂Cl₂/Hexane=¼), so as to obtain white solids (0.51 g, yield 12%).

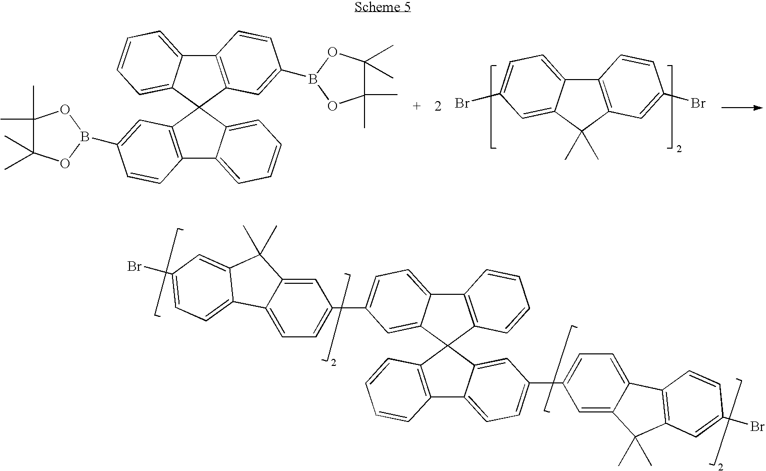

### EXAMPLE 6

### Synthesis of Tetra-Bromo Intermediate for Synthesis of Compound 8

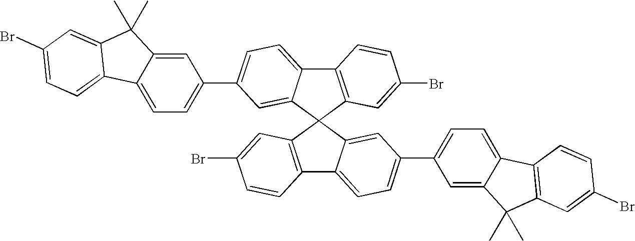

Referring to scheme 6-1, at room temperature and under nitrogen atmosphere, a solution of 2-bromofluorene (100 g; 0.41 mole) in DMSO (400 mL) was added to a 1 L three-necked flask. The solution was cooled to 0° C., and potassium tert-butoxide (137 g; 1.23 mole) was then added into the cooled solution. Next, the mixture was stirred at 0° C. for 1 hour, and CH₃I (231.8 g; 1.63 mole) was subsequently added into the mixture drop by drop. After completion of the CH₃I adding, the mixture was heated to room temperature, and reacted for 24 hours. After completion of the reaction, ethyl acetate (EA) was added to the reaction mixture (600 mL×3), and then the organic layer was separated, dehydrated with MgSO₄, and concentrated to obtain 2-bromo-9,9-dimethylfluorene 104.5 g (yield 81.6%).

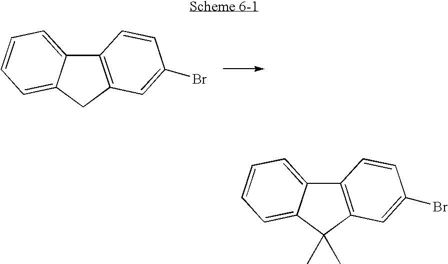

Referring to scheme 6-2, at room temperature and under nitrogen atmosphere, a solution of Mg (9.8 g; 0.41 mole) and Iodine (1 g; 7.7 mmole) in THF (100 mL) was added to a 1 L three-necked flask. The solution was heated to 60° C., and a solution of 2-bromo-9,9-dimethylfluorene (104 g; 0.38 mole) dissolved in 150 mL THF was added into the heated solution drop by drop. The mixture was then stirred for 2 hours. After completion of the reaction, the reaction mixture was cooled to room temperature, and 200 mL THF was added into the cooled mixture. The diluted mixture was subsequently iced at −78° C. for 10 minutes. Next, a solution of trimethyl borate (36.4 g; 0.35 mole) dissolved in 100 mL THF was added into the iced mixture drop by drop. After completion of the trimethyl borate adding, the iced mixture was stand for 30 minutes at −78° C., and then heated to room temperature, stirred for another 24 hours. After completion, solvent THF was removed by vacuum concentration, and 200 mL CH₂Cl₂ and 200 ml 10% HCl_{(aq)} were subsequently added, and stirred for 30 minutes. Water (150 ml×2) was then added. The organic layer was separated, dehydrated, filtered, and the filtrate was dropped into 2 L hexane to obtain solids. Finally, solids were filtered and dried to get 9,9-dimethylfluorene-2-boronic acid 42.8 g (yield 47.3%).

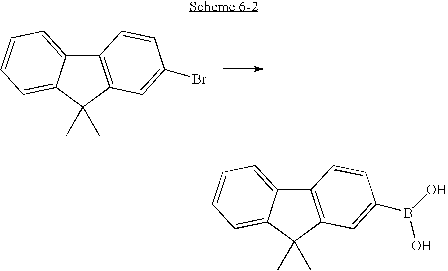

Referring to scheme 6-3, at room temperature and under nitrogen atmosphere, a solution of 2,2′-dibromo-9,9′-spirobiflurene (5 g; 10.5 mmole), 9,9-dimethylfluorene-2-boronic acid (7.5 g; 31.5 mmole), Tetrakis(triphenylphosphine)palladium(0) [0.23 g; 0.2 mmole], Na₂CO₃ (2 M; 20 mL), and 2-(dicyclo-hexylphosphino)biphenyl (0.174 g; 0.5 mmole) in toluene (75 mL) was added to a 100 mL three-necked flask. The solution was heated to 130° C., and stirred for 24 hours. After completion of the reaction, the reaction mixture is thermo filtrated; the filtrate was cooled to room temperature, and dropped into 750 mL methanol to obtain solids. Finally, the solids were filtered and dried to get 2,2′-bis(9,9-dimethylfluorene)-9,9′-spirobifluorene 3.5 g (yield 47.6%). MS (m/z, FAB⁺), 701,505,463,437,341,136

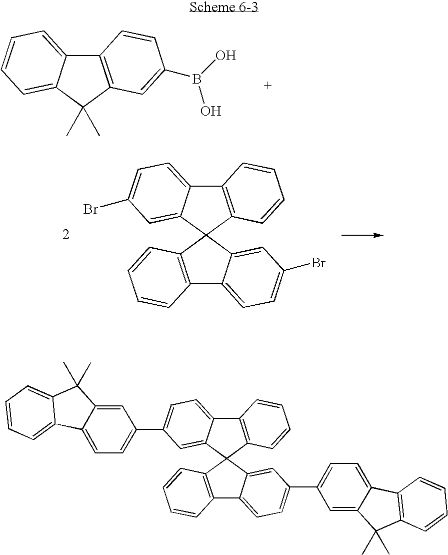

Referring to scheme 6-4, at room temperature and under nitrogen atmosphere, a solution of 2,2′-bis(9,9-dimethylfluorene)-9,9′-spirobifluorene (10 g; 14.3 mmole) in CH₂Cl₂ (200 mL) was added to a 500 mL three-necked flask, and then the solution was heated to 60° C. Next, a solution of Br₂ (9.13 g; 57 mmole) dissolved in 20 mL CH₂Cl₂ was added into the heated mixture drop by drop, and reacted for one hour. After completion of the reaction, the reaction mixture was cooled to room temperature, and the reaction mixture was dropped into 1000 mL methanol to obtain solids. Finally, the solids were filtered and dried to obtain tetra-bromo intermediate 5.5 g (yield 35%), MS (m/z, FAB⁺), 1016,564,435,282,154

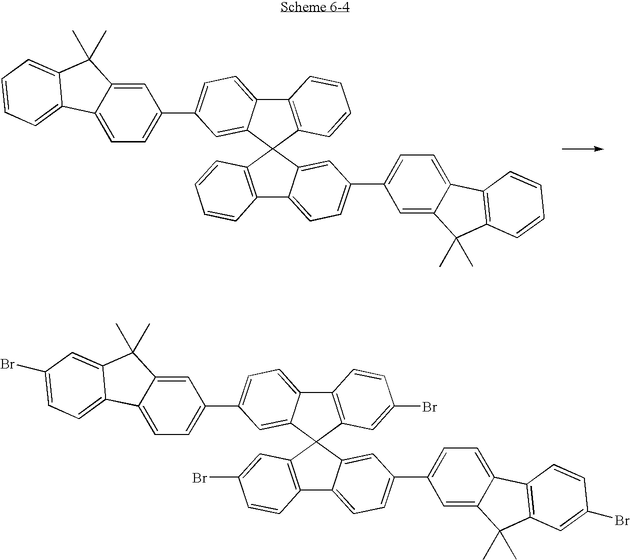

### EXAMPLE 7

### Synthesis of Compound 8

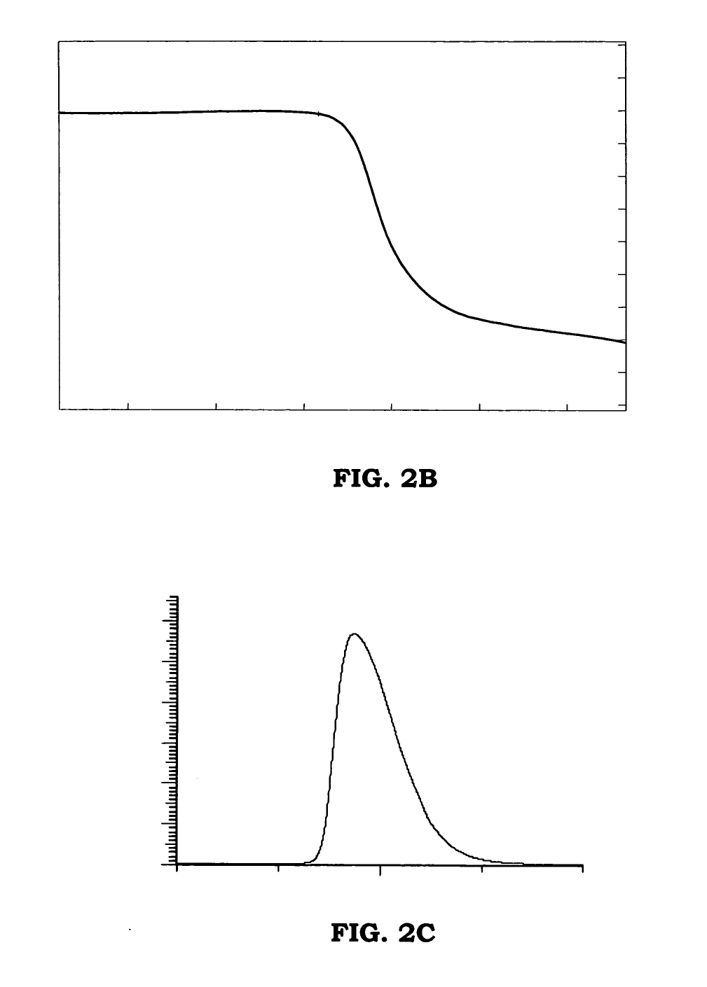

Referring to scheme 7, at room temperature and under nitrogen atmosphere, a solution of tetra-bromo intermediate (5 g; 5 mmole), N-phenyl-2-naphthylamine (6.5 g), Palladium(II) acetate (0.011 g; 0.05 mmole), 2-(dicyclo-hexylphosphino)biphenyl (0.052 g; 0.15 mmole), sodium tert-butoxide (3 g) in toluene (30 mL) was added to a 100 mL three-necked flask. The solution was heated to 130° C. and reacted for 24 hours. After completion of the reaction, the reaction mixture was cooled to room temperature, and the reaction mixture was dropped into 300 mL methanol to obtain solids. Subsequently, solids were filtered and dried to obtain crude product. Finally, crude product was purified by column chromatography to get compound 8 (1.08 g, yield 14%), MS (m/z, FAB⁺), 1570. T_{g}=210.9° C. (as shown in FIG. 2A), T_{d}=416.9° C. (as shown in FIG. 2B), and FIG. 2C shows the PL spectrum of compound 8 with λₘₐₓ=472.8 nm.

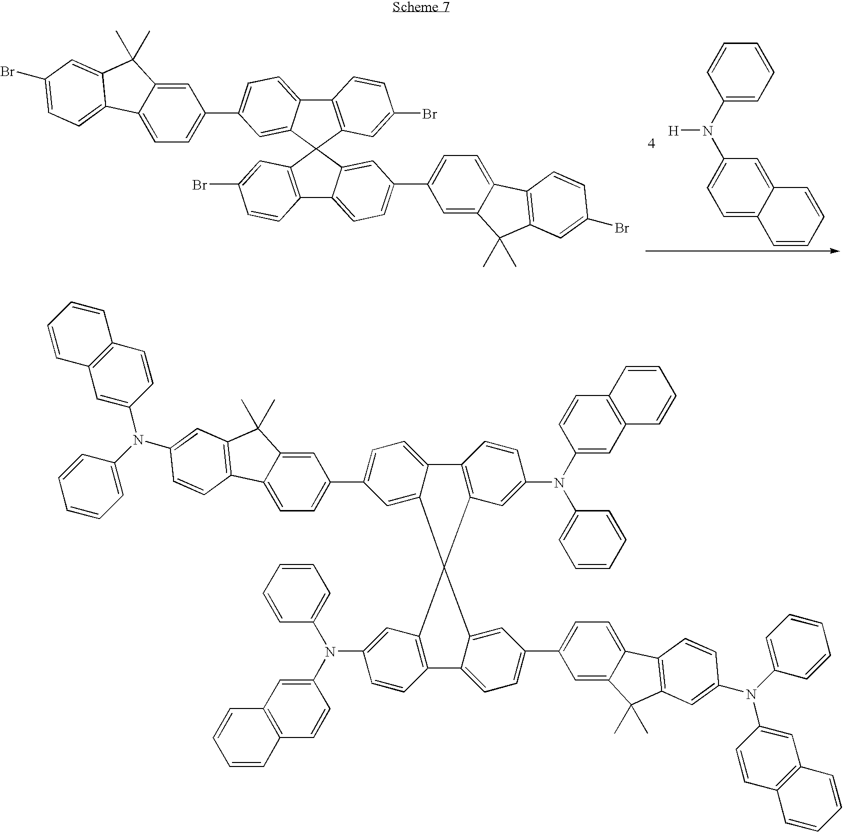

In a second embodiment of the present invention, an OLED comprising a multilayer structure for producing electroluminescence is provided. For realizing practical full-color displays, red-, green-, and blue-emitters with sufficiently high luminous efficiencies and color purity are required. Two common methods of tuning the color of an OLED are a) choosing an emission material with the appropriate intrinsic emission characteristics, or b) incorporating in a host transport material guest dopants with the appropriate emission characteristics. Introducing dopants in organic molecular films facilitates the control of a number of device properties such as electroluminescence (EL) Quantum efficiency, thermal stability, durability, and carrier injection and transport. Guest emitter is usually doped in host by co-evaporation or dispersion process, and receives energy from host in the way of energy transfer or carrier trap, so as to result in generating varying colors and enhancing the EL efficiency of OLEDs.

According to this embodiment, the mentioned multilayer structure comprises: a substrate; an anode layer; a hole transporting layer; an emitting layer comprising a oligofluorene-based compound of a general formula as following: 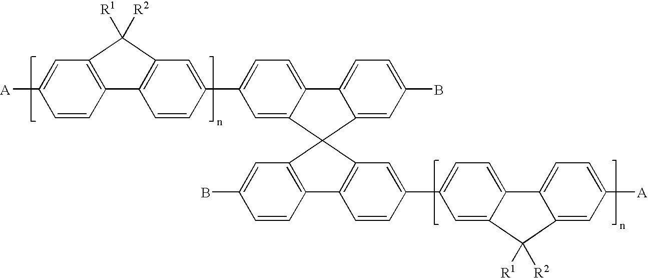
, an electron transporting layer; and a cathode layer. Furthermore, n of the oligofluorene-based compound of the emitting layer is an integer of 0 to 3, and when n=0, A is a polyaryl moiety, is 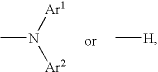
when 1≦n≦3, A is a polyaryl moiety or 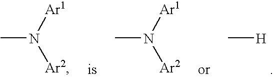
Additionally, Ar¹ and Ar² can be identical or different, and Ar¹ and Ar² are independently selected from the group consisting of: aryl moiety, hetero cycle, multiple fused ring, multiple fused ring with hetero atom(s). The selection of the polyaryl moiety is described in the first embodiment.

Moreover, the mentioned organic light emitting device can further comprise a hole injecting layer located between the anode and the hole transporting layer, and/or further comprise an electron injecting layer located between the cathode and the electron transporting layer.

In a third embodiment of the present invention, an organic light emitting device comprising a multilayer structure for producing electroluminescence is disclosed, wherein the multilayer structure comprises a substrate, an anode layer, a hole transporting layer, an emitting layer comprising a first oligofluorene-based compound doped with a second oligofluorene-based compound, an electron transporting layer, and a cathode layer. Furthermore, the general formula of the first oligofluorene-based compound is as following. 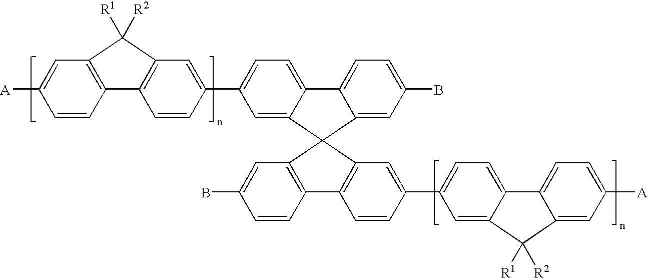
In the mentioned formula, n is an integer of 0 to 3, A is a polyaryl moiety, and B is hydrogen atom. The general formula of the second oligofluorene-based compound is as following. 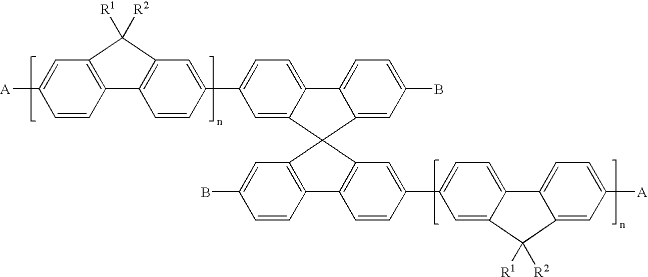
In the above general formula, n is an integer of 0 to 3, and
when n=0, A is a polyaryl moiety, is 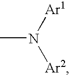
when 1≦n≦3, A is a polyaryl moiety, B is 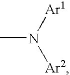
when 1≦n≦3, A is 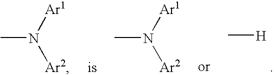
Additionally, Ar¹ and Ar² can be identical or different, and Ar¹ and Ar² are independently selected from the group consisting of: aryl moiety, hetero cycle, multiple fused ring, multiple fused ring with hetero atom(s). The selection of the polyaryl moiety is described in the first embodiment.

Moreover, the mentioned organic light emitting device can further comprise a hole injecting layer located between the anode and the hole transporting layer, and/or further comprise an electron injecting layer located between the cathode and the electron transporting layer.

General Method of Producing OLEDs

ITO-coated glasses with 15Ω□⁻¹ and 1500 μm in thickness are provided (purchased from Sanyo vacuum, hereinafter ITO substrate) and cleaned in a number of cleaning steps in an ultrasonic bath (e.g. detergent, deionized water). Before vapor deposition of the organic layers, cleaned ITO substrates are further treated by UV and ozone.

The organic layers are applied onto the ITO substrate in order by vapor deposition in a high-vacuum unit (10⁻⁶ Torr), such as: resistively heated quartz boats. The thickness of the respective layer and the vapor deposition rate (0.1˜0.3 nm/sec) are precisely monitored or set with the aid of a quartz-crystal monitor.

It is also possible, as described above, for individual layers to consist of more than one compound, i.e. in general a host material doped with a guest material. This is achieved by covaporization from two or more sources.

2,2′,2″-(1,3,5-benzinetriyl)tris(1-phenyl-1-H-benzimidazole) [TPBi] is used as the electron transporting/hole blocking layer in OLEDs of this invention, the structure formula of TPBI is shown as following:

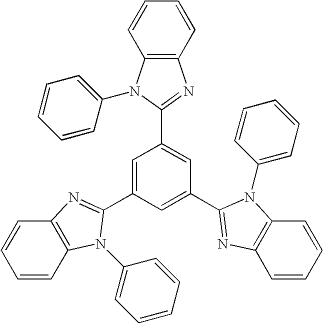

A typical OLED consists of low work function metals, such as Al, Mg, Ca, Li and K, as the cathode by thermal evaporation, and the low work function metals can help electrons injecting the electron transporting layer from cathode. In addition, for reducing the electron injection barrier and improving the OLED performance, a thin-film electron injecting layer is introduced between the cathode and the electron transporting layer. Conventional materials of electron injecting layer are metal halide or metal oxide with low work function, such as: LiF, MgO, or Li₂O.

On the other hand, after the OLEDs are fabricated, EL spectra and CIE coordination are measured by using a PR650 spectra scan spectrometer. Furthermore, the current/voltage, luminescence/voltage and yield/voltage characteristics are taken with a Keithley 2400 programmable voltage-current source. The above-mentioned apparatuses are operated at room temperature (about 20° C.) and under atmospheric pressure.

### EXAMPLE 8

Using a procedure analogous to the abovementioned general method, a blue-emitting OLED having the following structure was produced:

Device 1: ITO/Compound 9 (40 nm)/Compound 1 (30 nm)/TPBi (25 nm)/LiF (0.5 nm)/Al (120 nm)

, wherein the compound 9 is used as hole transport material, and its structure formula is as shown below. The compound 9 is described in Example 6 of the previous application of the same applicant (“Conjugated compounds containing triarylamine structural elements, and their use”, application number of U.S. application Ser. No. 11/242,007, application date is 2005 Oct. 4)

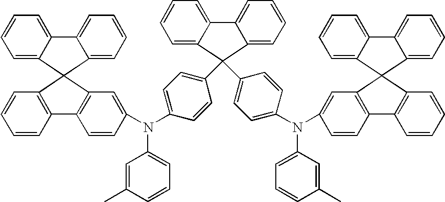

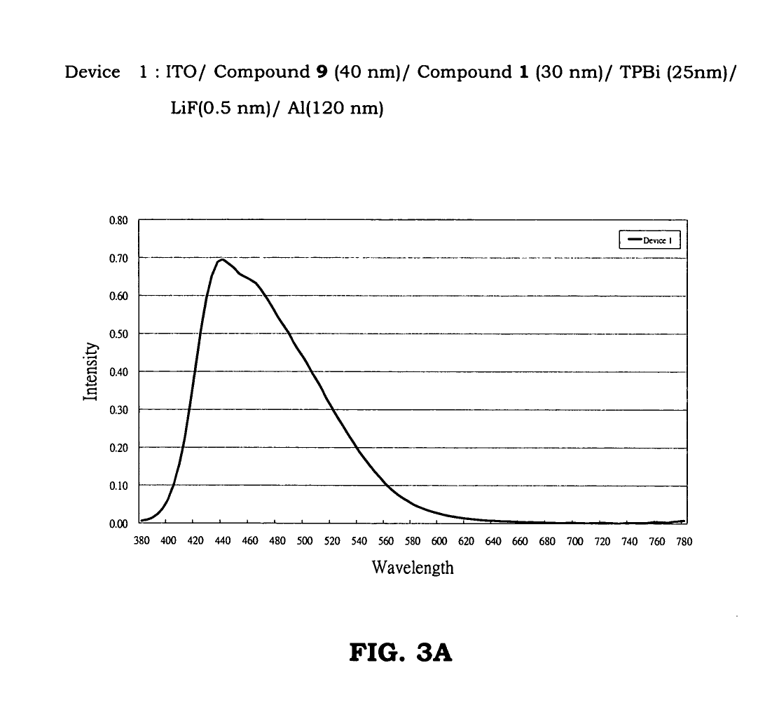

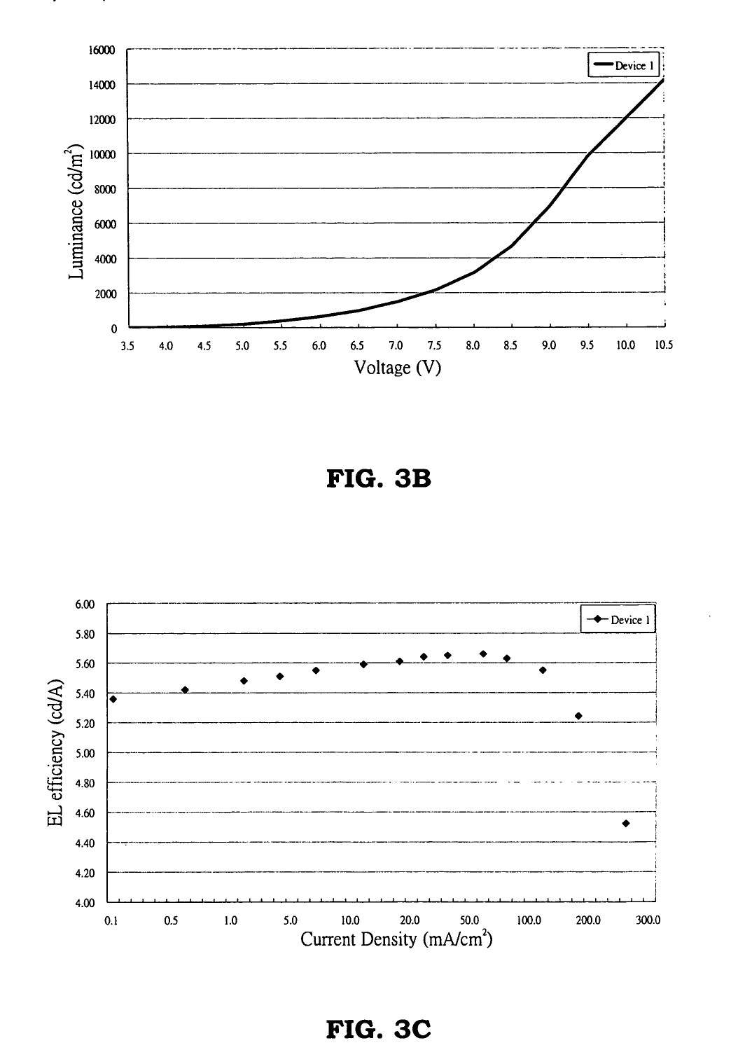

As shown in FIG. 3A, device 1 provided in this invention allows fluorescent emission in the deep-blue spectral range, and has an emission maximum at 440 nm, which gives CIE color coordinates of x=0.16 and y=0.15. Furthermore, referring to FIG. 3B, Luminance-Voltage characteristics of device 1 shows the trend that the brightness is increased with increasing driving voltage. The maximum brightness of device 1 is about 14,000 cd/m² at a driving voltage of 10.5 V. Moreover, referring to FIG. 3C, when current density is not higher than 100 mA/cm², EL efficiency of device 1 maintains in higher range (≧5.4 cd/A); when current density increases to about 300 mA/cm², EL efficiency of device 1 is slightly decreased to about 4.4 cd/A.

### EXAMPLE 9

Using a procedure analogous to the abovementioned general method, five blue-emitting OLEDs having the following structure was produced:

Device 2-1:

ITO/Compound 9 (40 nm)/compound 1 doped with 5 wt % compound 8 (30 nm)/TPBi (25 nm)/LiF (0.5 nm)/Al (120 nm)

Device 2-2:

ITO/Compound 9 (40 nm)/compound 1 doped with 10 wt % compound 8 (30 nm)/TPBi (25 nm)/LiF (0.5 nm)/Al (120 nm)

Device 2-3:

ITO/Compound 9 (40 nm)/compound 1 doped with 15 wt % compound 8 (30 nm)/TPBi (25 nm)/LiF (0.5 nm)/Al (120 nm)

Device 2-4:

ITO/Compound 9 (40 nm)/compound 1 doped with 20 wt % compound 8 (30 nm)/TPBi (25 nm)/LiF (0.5 nm)/Al (120 nm)

Device 2-5:

ITO/Compound 9 (40 nm)/compound 1 doped with 25 wt % compound 8 (30 nm)/TPBi (25 nm)/LiF (0.5 nm)/Al (120 nm)

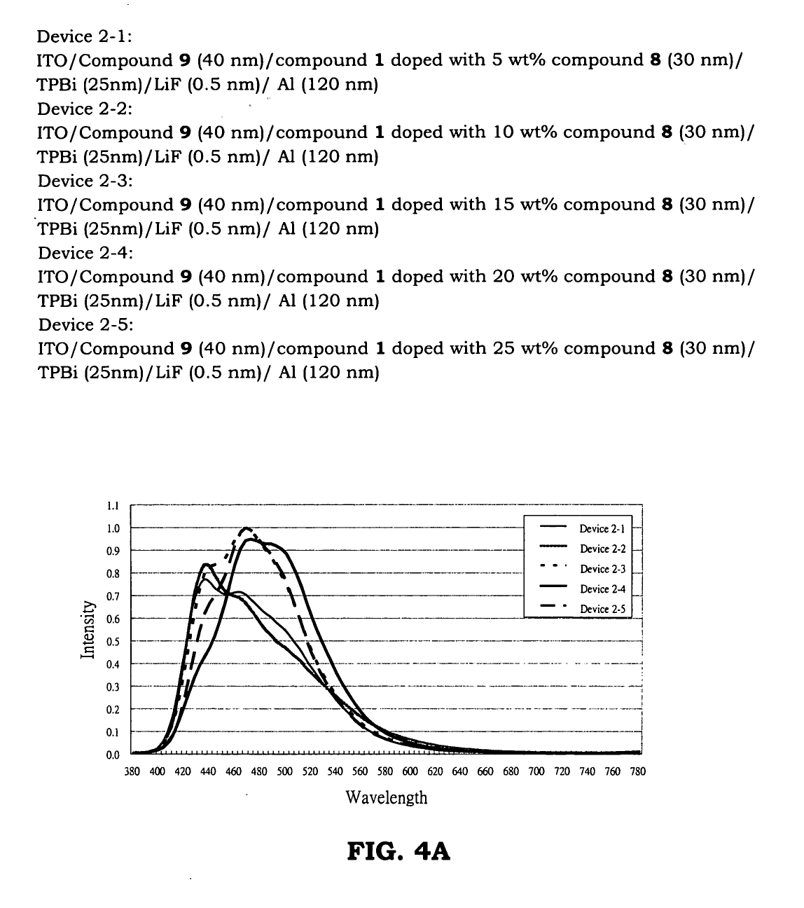

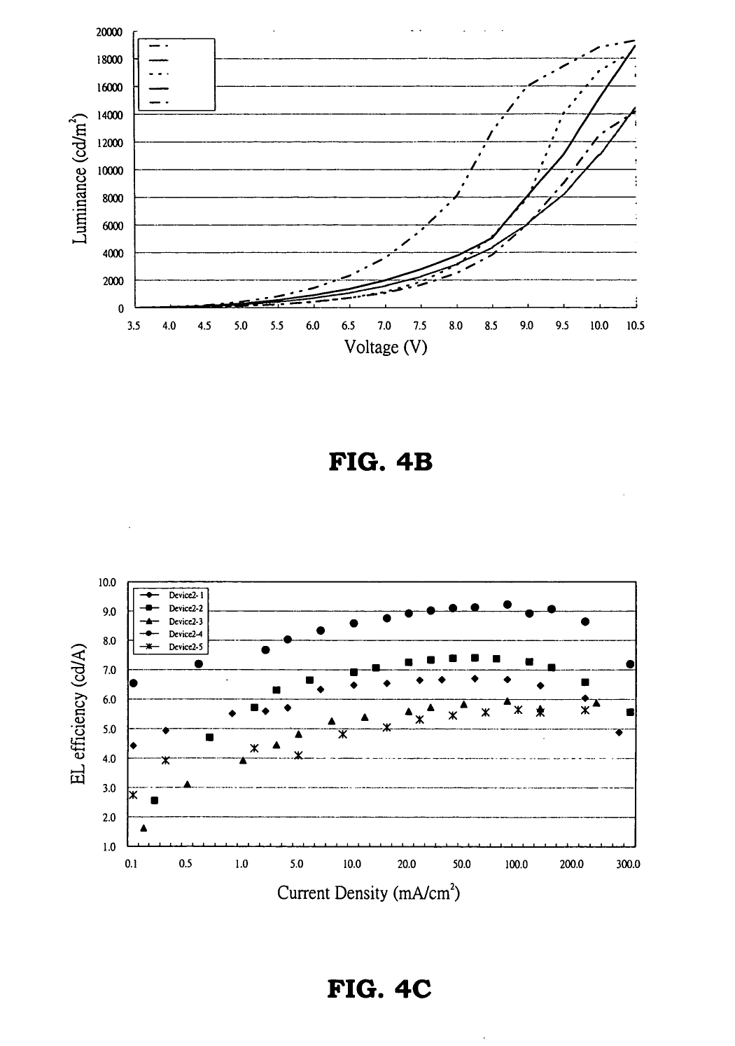

FIG. 4A indicates that the device 2-1 emitted a deep-blue colors two bands appear at 436 and 468 nm in the PL spectrums corresponding to CIE color coordinates of (0.15, 0.16). Additionally, when the concentration of guest dopants (compound 8) is equal to or higher than 15 wt %, band at 468 nm increased dramatically. The maximum emission wavelength and CIE color coordinates of device 2-1 to device 2-5 are listed in Table 2.

TABLE 2

| | λₘₐₓ (nm) | CIE (x, y) |
|---|---|---|
| Device 2-1 | 436 | (0.15, 0.16) |
| Device 2-2 | 436 | (0.15, 0.16) |
| Device 2-3 | 468 | (0.15, 0.19) |
| Device 2-4 | 472 | (0.15, 0.27) |
| Device 2-5 | 468 | (0.15, 0.20) |

Referring to FIG. 4B, device 2-1 exhibits the largest brightness at all driving voltage. Furthermore, when the brightness of device 2-1 increases to 10,000 cd/m², the driving voltage increases slightly to a relatively low value of 8.2 V. It is noteworthy that, when the driving voltage is lower than 9 V, Luminance-Voltage characteristics of device 2-3 and device 2-4 show similar trend; when the driving voltage is higher than 9 V, the brightness of device 2-3 dramatically increases.

Referring to FIG. 4C, when the current density is lower than 100 mA/cm², EL efficiency-current density characteristics of the devices shows the trend that the EL efficiency is increased with increasing current density; when current density is higher than 100 mA/cm², EL efficiency of devices are slightly decreased, but still maintain in high value (about 5V). Additionally, EL efficiency of device 2-4 is higher than those of other devices, and ranges from about 7 to 9 cd/A at all current density.

In the above preferred embodiments, the present invention employs spirobifluorene as core structure, which is with high photoluminescence (PL) and electroluminescence (EL) efficiencies, good thermal stability, and ready color-tuning through the introduction of fluorine-based on 2,2′ positions. Moreover, this invention is to provide a multilayered OLED with low driving voltage, high efficiency, and high thermal stability, wherein the OLED comprises the mentioned oligofluorene-based compounds as electro-luminescent materials or host-guest materials. The glass transition temperature (T_{g}) and thermal degradation temperature (T_{d}) of the mentioned oligofluorene-based are higher than 150° C. and 400° C. respectively. Therefore, this present invention does have the economic advantages for industrial applications.

To sum up, the present invention discloses an oligofluorene-based compound, wherein the general formula of the oligofluorene-based compound is as following: 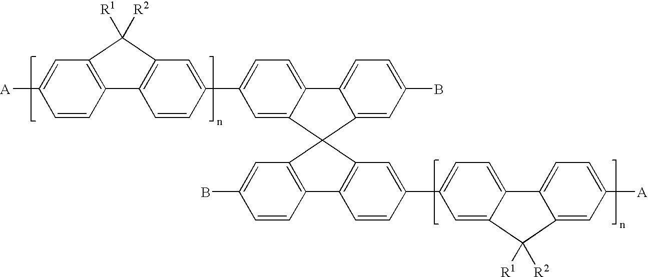
, wherein n is an integer of 0 to 3; and
when n=0, A is a polyaryl moiety, B is 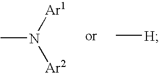
when 1≦n≦3, A is a polyaryl moiety or 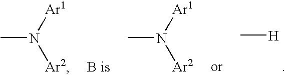
Furthermore, the mentioned oligofluorene-based compound can be used as electro-luminescent materials or host-guest materials.

Obviously many modifications and variations are possible in light of the above teachings. It is therefore to be understood that within the scope of the appended claims the present invention can be practiced otherwise than as specifically described herein. Although specific embodiments have been illustrated and described herein, it is obvious to those skilled in the art that many modifications of the present invention may be made without departing from what is intended to be limited solely by the appended claims.

What is claimed is:

1. An oligofluorene-based compound with a general formula as following: 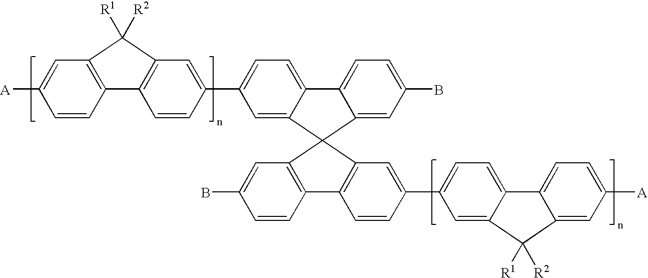
, wherein n is an integer of 0 to 3;
when n=0, A is a polyaryl moiety, and B is 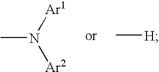
when 1≦n≦3, A is a polyaryl moiety or

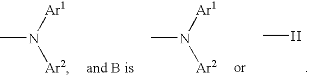

2. The compound as claimed in claim 1, wherein the polyaryl moiety is selected from the group consisting of:

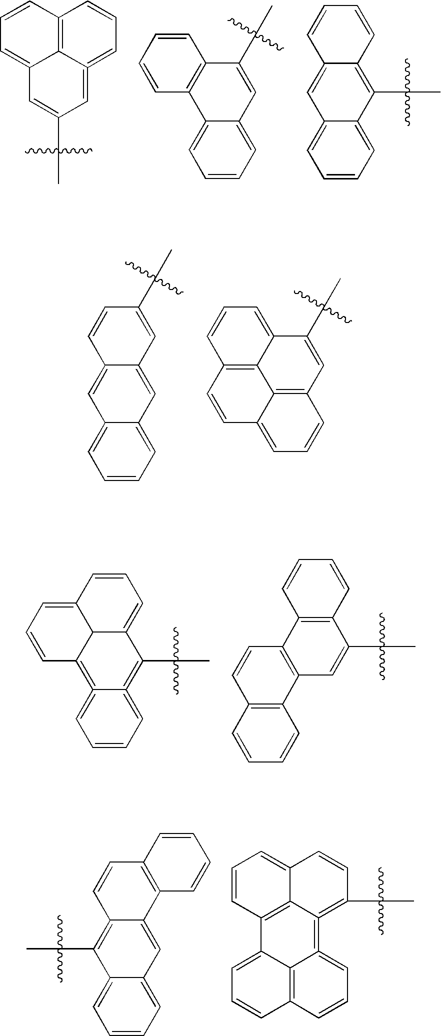

3. The compound as claimed in claim 1, wherein Ar¹ and Ar² are identical or different, and Ar¹ and Ar² are independently selected from the group consisting of: aryl moiety, hetero cycle, multiple fused ring, multiple fused ring with hetero atom(s).

4. The compound as claimed in claim 1, wherein the compound is used in organic electroluminescence devices.

5. The compound as claimed in claim 1, wherein the compound is used as host material or as guest dopant material in organic electroluminescence devices.

6. The compound as claimed in claim 5, wherein the compound is used as host material in organic electroluminescence devices, wherein A is a polyaryl moiety, and B is hydrogen atom.

7. The compound as claimed in claim 5, wherein the compound is used as guest dopant material in organic electroluminescence devices, wherein n=0, A is a polyaryl moiety, and B is

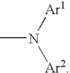

8. The compound as claimed in claim 5, wherein the compound is used as guest dopant material in organic electroluminescence devices, wherein 1≦n≦3, A is a polyaryl moiety, and B is

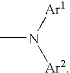

9. The compound as claimed in claim 5, wherein the compound is used as guest dopant material in organic electroluminescence devices, wherein 1≦n≦3, A is

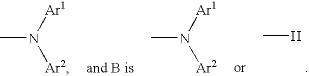

10. An organic light emitting device comprising a multilayer structure for producing electroluminescence, wherein the multilayer structure comprises:
a substrate;
an anode layer;
a hole transporting layer;
an emitting layer comprising a oligofluorene-based compound of a general formula as following: 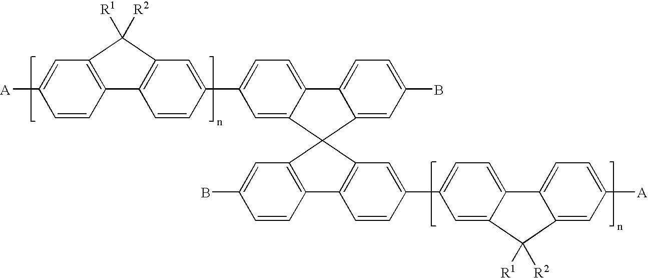
an electron transporting layer; and
a cathode layer,
wherein n of the oligofluorene-based compound of the emitting layer is an integer of 0 to 3, and
when n=0, A is a polyaryl moiety, B is 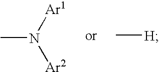
when 1≦n≦3, A is a polyaryl moiety or

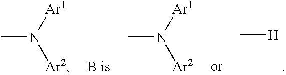

11. The organic light emitting device as claimed in claim 10, wherein the polyaryl moiety is selected from the group consisting of:

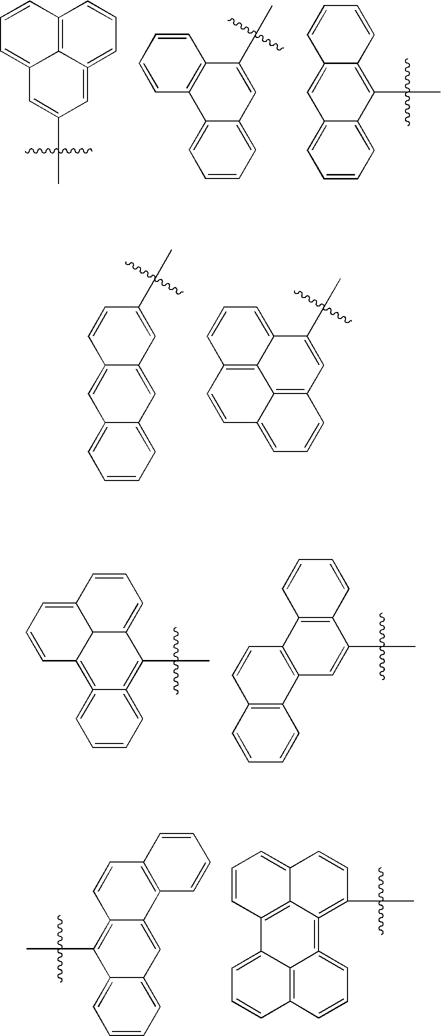

12. The organic light emitting device as claimed in claim 10, wherein Ar¹ and Ar² are identical or different, and Ar¹ and Ar² are independently selected from the group consisting of: aryl moiety, hetero cycle, multiple fused ring, multiple fused ring with hetero atom(s).

13. The organic light emitting device as claimed in claim 10, further comprising a hole injecting layer located between the anode and the hole transporting layer.

14. The organic light emitting device as claimed in claim 10, further comprising an electron injecting layer located between the cathode and the electron transporting layer.

15. An organic light emitting device comprising a multilayer structure for producing electroluminescence, wherein the multilayer structure comprises:
a substrate;
an anode layer;
a hole transporting layer;
an emitting layer comprising a first oligofluorene-based compound doped with a second oligofluorene-based compound;
an electron transporting layer; and
a cathode layer
, wherein the general formula of the first oligofluorene-based compound is as following: 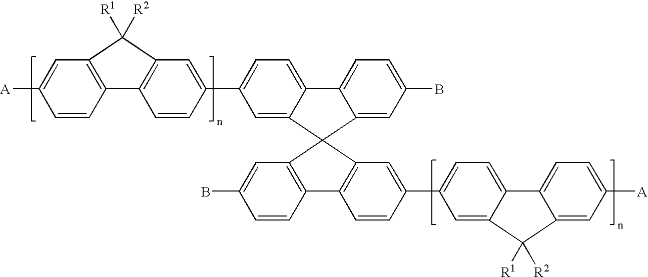
, wherein n is an integer of 0 to 3, A is a polyaryl moiety, and B is hydrogen atom; the general formula of the second oligofluorene-based compound is as following: 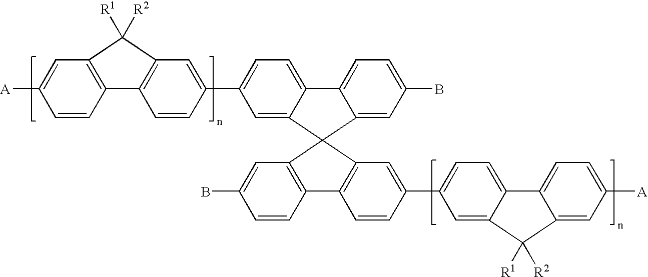
, wherein n is an integer of 0 to 3,
when n=0, A is a polyaryl moiety, and B is 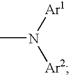
when 1≦n≦3, A is a polyaryl moiety, and B is 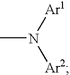
when 1≦n≦3, A is

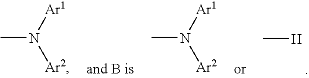

16. The organic light emitting device as claimed in claim 15, wherein the polyaryl moiety is selected from the group consisting of:

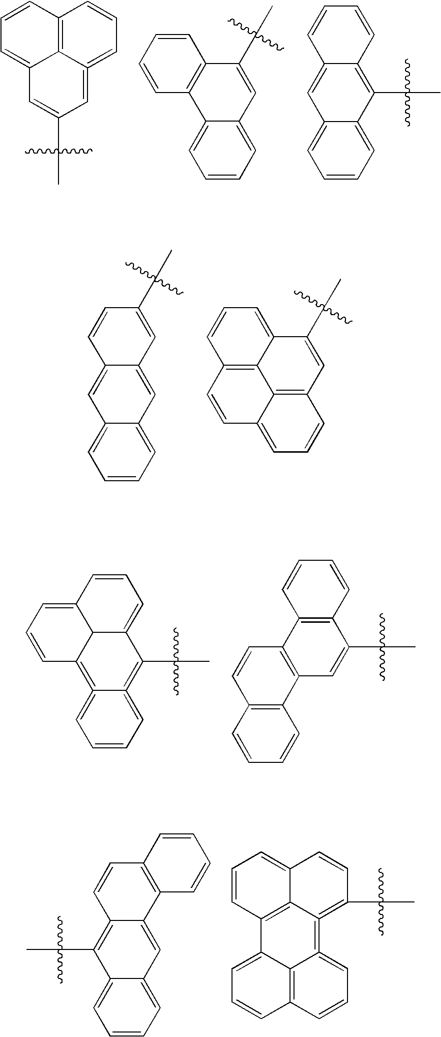

17. The organic light emitting device as claimed in claim 15, wherein Ar¹ and Ar² are identical or different, and Ar¹ and Ar² are independently selected from the group consisting of: aryl moiety, hetero cycle, multiple fused ring, multiple fused ring with hetero atom(s).

18. The organic light emitting device as claimed in claim 15, further comprising a hole injecting layer located between the anode and the hole transporting layer.

19. The organic light emitting device as claimed in claim 15, further comprising an electron injecting layer located between the cathode and the electron transporting layer.
